(19) United States
(12) Patent Application Publication
(10) Pub. No.: US 2016/0302308 A1
(43) Pub. Date: Oct. 13, 2016

(54) PRINTED CIRCUIT BOARD, ELECTRONIC COMPONENT MODULE AND METHOD OF MANUFACTURING THE SAME

(71) Applicant: Samsung Electro-Mechanics Co., Ltd., Suwon-si (KR)

(72) Inventors: Jeong Ho LEE, Suwon-Si (KR); Young Do KWEON, Suwon-Si (KR); Hyoung Joon KIM, Suwon-Si (KR); Seung Yeop KOOK, Suwon-Si (KR)

(73) Assignee: Samsung Electro-Mechanics Co., Ltd., Suwon-si (KR)

(21) Appl. No.: 14/871,065

(22) Filed: Sep. 30, 2015

(30) Foreign Application Priority Data
Apr. 7, 2015 (KR) 10-2015-0048937

(51) Int. Cl. H05K 1/14; H05K 1/11; H05K 1/18; H05K 3/36; H05K 3/30

(52) U.S. Cl. CPC H05K 1/14; H05K 3/36; H05K 3/303; H05K 1/181; H05K 1/111; H05K 1/115; H05K 2201/048

(57) ABSTRACT

There are provided a printed circuit board, an electronic component module and a method of manufacturing the same. The printed circuit board includes a circuit board including a through hole and a first circuit pattern, and a connection board having a microcircuit structure including a second circuit pattern, the connection board accommodated in the through hole.

### CROSS-REFERENCE TO RELATED APPLICATION

This application claims the benefit under 35 USC 119(a) of Korean Patent Application No. 10-2015-0048937 filed on Apr. 7, 2015, with the Korean Intellectual Property Office, the entire disclosure of which is incorporated herein by reference for all purposes.

### BACKGROUND

1. Field

The present disclosure relates to a printed circuit board and an electronic component module, and a method of manufacturing the same.

2. Description of Related Art

Portable electronic devices, such as mobile devices and tablet personal computers, are becoming increasing smaller and thinner. Further, portable electronic devices increasingly provide an improved performance and a high-level integration. To produce these electronic products, there exists a demand to improve the performance and integration of core components of the electronic products, such as central processing units (CPU), graphic processing units (GPU), application processors (AP), and the like. In the field of package board manufacturing, there is an increasing demand to develop suitable technologies and structures to implement micropatterns having a line width of 3 μm or less to produce these integrated high-performance core components.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a printed circuit board including a circuit board including a through hole and a first circuit pattern, and a connection board having a microcircuit structure including a second circuit pattern, the connection board accommodated in the through hole.

The circuit board may be a multilayer board including a plurality of circuit layers and insulating layers, and at least one of the insulating layers is interposed between the plurality of circuit layers.

The first circuit pattern includes first pads for mounting electronic components.

The microcircuit structure may be disposed on one surface or both surfaces of the connection board.

The microcircuit structure may include microcircuit layers disposed on both surfaces of the connection board and electrically connected to each other by a via.

The microcircuit structure may include a plurality of circuit layers and insulating layers, and at least one of the insulating layers may be interposed between the plurality of circuit layers.

The insulating layer may be a photosensitive insulating layer.

The second circuit pattern may include a signal line for connecting electronic components to each other.

The second circuit pattern may include second pads for mounting electronic components.

The second circuit pattern may include a micropattern having a pitch smaller than that of the first circuit pattern.

The general aspect of the printed circuit board may further include a build-up layer including an insulating build-up layer and a circuit build-up layer disposed on the circuit board and the connection board.

The general aspect of the printed circuit board may further include a solder resist layer disposed on the circuit board.

The general aspect of the printed circuit board may further include a resin filler disposed between the connection board and the through hole.

The resin filler may be a solder resist.

In another general aspect, an electronic component module includes a printed circuit board including a circuit board having a through hole and a first circuit pattern, and a connection board having a microcircuit structure including a second circuit pattern, the connection board accommodated in the through hole, and electronic components mounted on one surface or both surfaces of the printed circuit board.

The second circuit pattern includes a micropattern having a pitch smaller than that of the first circuit pattern.

In another general aspect, a method of manufacturing a printed circuit board involves preparing a circuit board having a through hole and including a first circuit pattern, and inserting a connection board in the through hole. The connection board may include a microcircuit structure comprising a second circuit pattern.

The general aspect of the method may further involve preparing the connection board prior to the inserting of the connection board in the through hole such that the circuit board is a multilayer board including circuit layers and insulating layers disposed on a first side of a core insulating layer and on a second side of the core insulating layer opposite the first side, a via electrically connecting the first side to the second side of the connection board.

The general aspect of the method may further involve mounting one or more electronic components on one surface or both surfaces of the printed circuit board.

Other features and aspects will be apparent from the following detailed description, the drawings, and the claims.

### BRIEF DESCRIPTION OF THE DRAWINGS

FIG. 1 is a cross-sectional view of an example of a printed circuit board according to the present disclosure.

FIG. 2 is a cross-sectional view of another example of a printed circuit board according to the present disclosure.

FIG. 3 is a cross-sectional view of another example of a printed circuit board according to the present disclosure.

FIG. 4 is a cross-sectional view of another example of a printed circuit board according to the present disclosure.

FIG. 5 is a cross-sectional view of another example of a printed circuit board according to the present disclosure.

FIG. 6 is a cross-sectional view of an example of an electronic component module according to the present disclosure.

FIG. 7 is a cross-sectional view of another example of an electronic component module according to the present disclosure.

FIG. 8 is a flowchart illustrating an example of a method of manufacturing a printed circuit board and an electronic component module according to the present disclosure.

FIGS. 9 through 22 are cross-sectional views sequentially illustrating an example of a method of manufacturing a printed circuit board and an electronic component module according to FIG. 8.

FIG. 23 is a flowchart illustrating another example of a method of manufacturing a printed circuit board and an electronic component module according to the present disclosure.

FIGS. 24 through 38 are cross-sectional views sequentially illustrating an example of a method of manufacturing a printed circuit board and an electronic component module according to FIG. 23.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

An aspect of the present disclosure may provide a printed circuit board in which warpage may be easily controlled, and a method of manufacturing the same.

An aspect of the present disclosure may also provide a printed circuit board having a micropattern and a micro pitch, and a method of manufacturing the same.

An aspect of the present disclosure may also provide a printed circuit board having a pattern for forming connections between a plurality of electronic components, and a method of manufacturing the same.

An aspect of the present disclosure may also provide a printed circuit board allowing for an increased degree of design freedom and allowing a product in which the printed circuit board is used to be miniaturized and thinned, and a method of manufacturing the same.

An aspect of the present disclosure may also provide an electronic component module in which the printed circuit board is used.

In the drawings, the shapes and dimensions of elements may be exaggerated for clarity, and the same reference numerals will be used throughout to designate the same or like elements.

### Printed Circuit Board

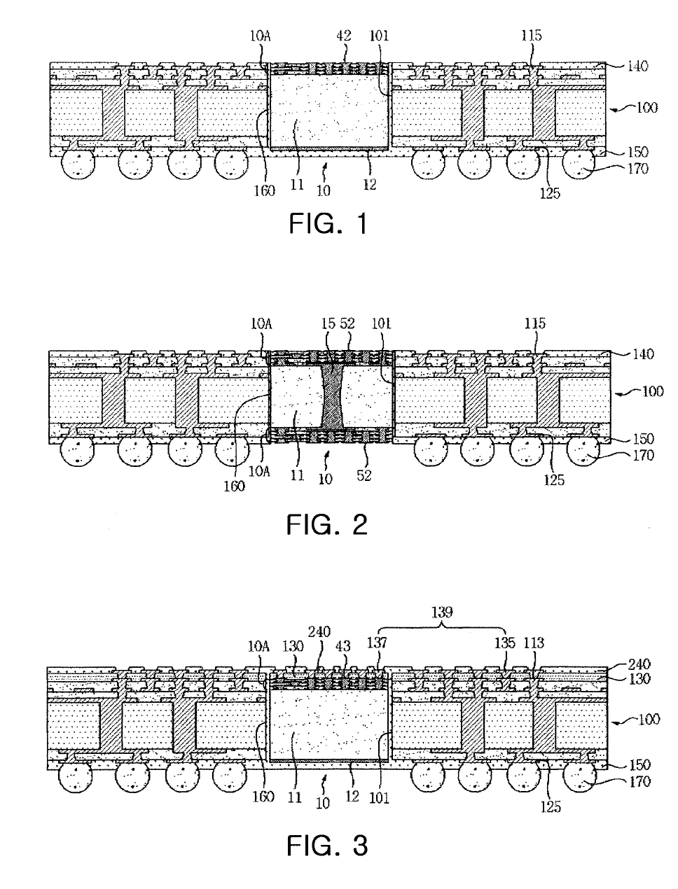

FIG. 1 illustrates a cross-sectional view of an example of a printed circuit board.

Referring to FIG. 1, the printed circuit board includes a circuit board 100 having a through hole 101 and a connection board 10 accommodated in the through hole 101.

In this example, the circuit board 100 is a multilayer printed circuit board including a plurality of circuit layers and a plurality of insulating layers, and at least one of the insulating layers is interposed between the circuit layers so as to insulate the circuit layers from each other; however, the present disclosure is not limited thereto. Further, according to the illustrated example, the circuit board 100 may be a ball grid array (BGA) board including a general core board.

In this example, the circuit board 100 also includes blind vias and through-vias connecting interlayer circuit layers to each other.

In this example, the circuit layers includes first pads 115 and 125 for forming connections to external products, such as electronic components or the like.

In this example, the connection board 10 includes a core insulating layer 11, a microcircuit structure 10A disposed on an upper surface of the core insulating layer 11, and a metal layer 12 disposed on a lower surface of the core insulating layer 11.

In this example, the microcircuit structure 10A includes a plurality of circuit layers and a plurality of insulating layers, and at least one of the insulating layers is interposed between the circuit layers so as to insulate the plurality of circuit layers from each other.

The circuit layers of the microcircuit structure 10A may have a micropattern having a pitch smaller than that of the circuit layers of the circuit board 100. According to one example, the micropattern may have a line width of 3 μm or less.

The microcircuit structure 10A may also include vias connecting interlayer circuit layers to each other.

The circuit layers of the microcircuit structure 10A may include a circuit pattern serving as a signal line connecting a plurality of electronic components mounted on the printed circuit board to each other.

In this example, the circuit layers of the microcircuit structure 10A includes second pads 42 for forming connections to external products such as electronic components, or the like.

In this example, the second pads 42 have a pitch smaller than that of the first pads 115 and 125.

The metal layer 12 is formed on a lower surface of the connection board 10 to contribute to controlling warpage of the printed circuit board and a heat dissipation effect of the printed circuit board.

As the insulating layer used in the microcircuit structure 10A, a photosensitive insulating layer may be used so that microcircuits may easily be formed. As the insulating layer used in the microcircuit structure 10A, a photosensitive insulating layer having a level of surface roughness lower than that of a material of a general resin insulating layer, for example, a photosensitive insulating layer not containing a glass sheet may be used.

Generally, a relatively expensive product such as a silicon interposer, or the like, is required in order to connect electronic components to each other. However, according to the present embodiment, a general resin board may be used, whereby a mismatch of coefficients of thermal expansion between an interposer board and an electronic component mounted on the interposer board may be significantly decreased, a degree of adhesion between the interposer board and an electronic component mounted on the interposer board may be improved, and a relatively inexpensive interposer may be implemented.

In addition, the core insulating layer of the connection board may be relatively thicker than the insulating layer of the circuit board, whereby warpage of the printed circuit board may be easily controlled.

Further, the microcircuit structure may be formed on a portion of the connection board to decrease an area to which a novel method is applied, whereby investment costs may be decreased and existing infrastructure may be utilized as much as possible.

Meanwhile, the circuit layers used in the circuit board 100 and the microcircuit structure 10A may be formed of any conductive material for a circuit used in the field of printed circuit boards. For example, the circuit layers may be formed of copper (Cu).

In addition, the metal layer 12 of the connection board 10 may be formed of the same material as that of a general circuit layer.

The insulating layers used in the circuit board 100 and the core insulating layer 11 of the connection board 10 may be formed of any insulating resin generally used as an insulating material in the case of printed circuit boards, for example, a thermosetting resin such as an epoxy resin, a thermoplastic resin such as polyimide, a resin formed by impregnating a reinforcing material such as a glass fiber or an inorganic filler in the thermosetting resin and the thermoplastic resin. For example, the insulating layers may be formed of a resin such as prepreg, Ajinomoto build-up film (ABF), FR-4, bismaleimide triazine (BT), or the like.

A resin filler 160 may be disposed between the circuit board 100 and the connection board 10. The resin filler 160 may be formed of a material generally used as an interlayer insulating material in the manufacturing of printed circuit boards or a solder resist.

Additionally, general liquid-state or film-type solder resist layers 140 and 150 may be formed as protective layers on the outermost layers of the circuit board 100 and the connection board 10, while exposing the plurality of pads 115 and 125 externally.

The solder resist layers may be formed in order to protect circuit patterns formed on the outermost circuit layers and electrically insulate the circuit patterns from each other, and have openings formed therein in order to expose the pads connected to the external product.

Surface treatment layers may be selectively and additionally formed on the pads exposed through the openings of the solder resist layers.

The surface treatment layer may be formed by any method known in the art, for example, electro gold plating, immersion gold plating, organic solderability preservative (OSP) or immersion tin plating, immersion silver plating, direct immersion gold (DIG) plating, hot air solder leveling (HASL), or the like.

The pads formed as described above may be used as pads for wire bonding, pads for bumps or pads for soldering for mounting external connection terminals such as solder balls, depending on a purpose thereof.

In the illustrated example, solder balls 170 are illustrated as external connection terminals formed on the first pads 125.

FIG. 2 illustrates a cross-sectional view of another example of a printed circuit board according to the present disclosure. Descriptions of components overlapped with those of the printed circuit board described above, among components of the printed circuit board illustrated in FIG. 2, will be omitted.

Referring to FIG. 2, the printed circuit board includes a circuit board 100 and a connection board 10 positioned to penetrate through the circuit board 100.

The connection board 10 includes a core insulating layer 11 and microcircuit structures 10A formed on both surfaces of the core insulating layer 11. The microcircuit structures 10A formed on both surfaces of the core insulating layer 11 may be electrically connected to each other by a via 15 penetrating through the core insulating layer 11.

In this example, the microcircuit structures 10A includes a plurality of circuit layers and a plurality of insulating layers, and at least one of the insulating layers is interposed between the circuit layers in order to insulate the plurality of circuit layers from each other.

The circuit layers of the microcircuit structure 10A have a micropattern having a pitch smaller than that of the circuit layers of the circuit board 100.

The microcircuit structure 10A may also include vias connecting interlayer circuit layers to each other.

The circuit layers of the microcircuit structure 10A may include a circuit pattern serving as a signal line connecting a plurality of electronic components mounted on the printed circuit board to each other.

The circuit layers of the microcircuit structure 10A may include second pads 52 for forming connections to external products such as electronic components, or the like.

The second pads 52 may have a pitch smaller than that of the first pads 115 and 125.

As the insulating layer used in the microcircuit structure 10A, a photosensitive insulating layer may be used so that microcircuits may be easily formed. As the insulating layer used in the microcircuit structure 10A, a photosensitive insulating layer having a level of surface roughness lower than that of a material of a general resin insulating layer, for example, a photosensitive insulating layer, not containing a glass sheet, may be used.

Generally, a relatively expensive product such as a silicon interposer, or the like, is required in order to connect electronic components to each other. However, according to the present embodiment, a general resin board may be used, whereby a mismatch of coefficients of thermal expansion between an interposer board and an electronic component mounted on the interposer board may be significantly decreased, a degree of adhesion between the interposer board and an electronic component mounted on the interposer board may be improved, and a relatively inexpensive interposer may be implemented.

In addition, the core insulating layer of the connection board may be relatively thicker than the insulating layer of the circuit board, whereby the warpage of the printed circuit board may be easily controlled.

Further, the microcircuit structure may be formed on portions of both surfaces of the connection board to decrease an area to which a novel method is applied, whereby investment costs may be decreased and existing infrastructure may be utilized as much as possible. Further, the electronic components may be mounted on both connection boards, such that an effect similar to 3-dimensional (3D) stacking may be obtained.

FIG. 3 illustrates a cross-sectional view of another example of a printed circuit board according to the present disclosure. Descriptions of components overlapped with those of the printed circuit boards described above, among components of the printed circuit board illustrated in FIG. 3, will be omitted.

Referring to FIG. 3, the printed circuit board includes a circuit board 100 and a connection board 10 positioned to penetrate through the circuit board 100.

The connection board 10 have a core insulating layer 11, a microcircuit structure 10A disposed on an upper surface of the core insulating layer 11, and a metal layer 12 disposed on a lower surface of the core insulating layer 11.

One or more build-up layers including insulating build-up layers 130 and circuit build-up layers 139 are formed on circuit layers 113 and 43 of the circuit board 100 and the connection board 10, respectively.

Additionally, in this example, a general liquid-state or film-type solder resist layer 240 is formed as a protective layer on the outermost circuit build-up layer 139, while exposing a plurality of pads 135 and 137.

According to this example, the build-up layers may be simultaneously formed on the circuit board 100 and the connection board 10, such that a degree of design freedom of the printed circuit board may be improved depending on a type of electronic component in which the printed circuit board is used.

FIGS. 4 and 5 illustrate cross-sectional views illustrating additional examles of printed circuit boards. Descriptions of components overlapped with those of the printed circuit boards described above, among components of the printed circuit boards illustrated in FIGS. 4 and 5, will be omitted.

Referring to FIG. 4, the printed circuit board includes a circuit board 100 and a connection board 10 positioned to penetrate through the circuit board 100.

As the circuit board 100, a general coreless board, that is, a thin board, may be used.

The connection board 10 includes a core insulating layer 11, a microcircuit structure 10A disposed on an upper surface of the core insulating layer 11, and a metal layer 12 disposed on a lower surface of the core insulating layer 11.

Referring to FIG. 5, the printed circuit board includes a circuit board 100 and a connection board 10 positioned to penetrate through the circuit board 100.

As the circuit board 100, a general coreless board, that is, a thin board, may be used.

The connection board 10 includes a core insulating layer 11 and microcircuit structures 10A formed on both surfaces of the core insulating layer 11. The microcircuit structures 10A formed on both surfaces of the core insulating layer 11 may be electrically connected to each other by a via 15 penetrating through the core insulating layer 11.

### Electronic Component Module

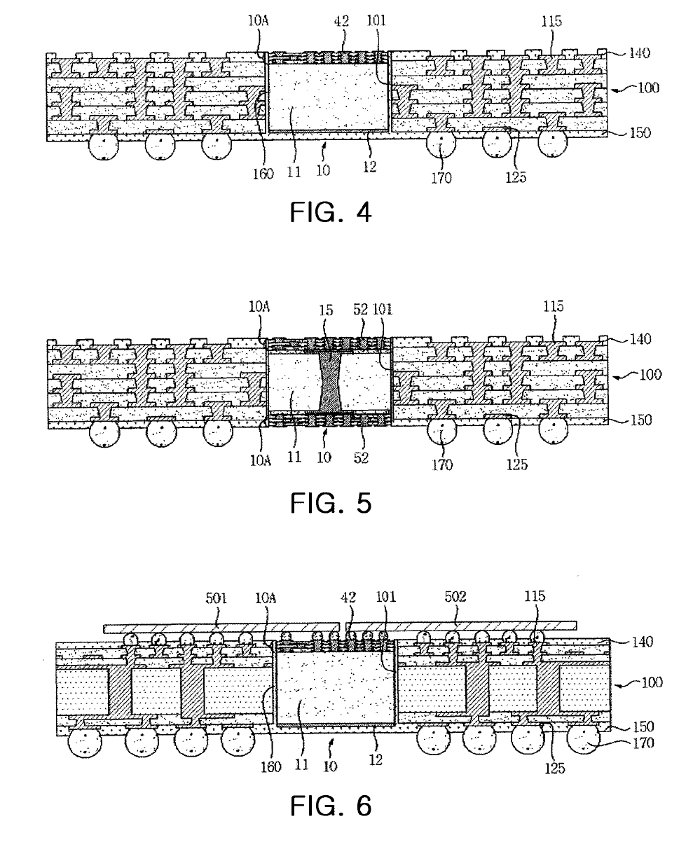

FIG. 6 illustrates a cross-sectional view of an example of an electronic component module according to the present disclosure. Descriptions of components overlapped with those of the printed circuit boards described above, among components of the electronic component module illustrated in FIG. 6, will be omitted.

Referring to FIG. 6, the electronic component module includes electronic components 501 and 502 mounted on a printed circuit board.

The printed circuit board includes a circuit board 100 having a through hole 101 and a connection board 10 accommodated in the through hole 101.

The circuit board 100 is a multilayer printed circuit board including a plurality of circuit layers and a plurality of insulating layers, and at least one of the insulating layers is interposed between the circuit layers in order to insulate the plurality of circuit layers from each other. For example, the circuit board 100 may be a BGA board including a general core board.

The circuit layers includes first pads 115 and 125 for forming connections to external products such as electronic components, or the like.

The electronic components 501 and 502 are mounted on the first pads 115 through flip-chip bonding, solder balls 170 may be provided as external connection terminals on the first pads 125, and the printed circuit board may be connected to an external product such as a main board (not illustrated) through the solder balls 170.

The connection board 10 includes a core insulating layer 11, a microcircuit structure 10A disposed on an upper surface of the core insulating layer 11, and a metal layer 12 disposed on a lower surface of the core insulating layer 11.

The microcircuit structure 10A includes a plurality of circuit layers and a plurality of insulating layers interposed between the plurality of circuit layers in order to insulate the plurality of circuit layers from each other.

The circuit layers of the microcircuit structure 10A may have a micropattern having a pitch smaller than that of the circuit layers of the circuit board 100.

The circuit layers of the microcircuit structure 10A may include a circuit pattern serving as a signal line connecting a plurality of electronic components mounted on the printed circuit board to each other.

In this example, the circuit layers of the microcircuit structure 10A include second pads 42 for forming connections to external products such as electronic components, or the like.

The second pads 42 have a pitch smaller than that of the first pads 115 and 125.

The metal layer 12 is formed on a lower surface of the connection board 10 to contribute to controlling warpage of the printed circuit board and a heat dissipation effect of the printed circuit board.

As the insulating layer used in the microcircuit structure 10A, a photosensitive insulating layer may be used so that microcircuits may be easily formed. As the insulating layer used in the microcircuit structure 10A, a photosensitive insulating layer having a level of surface roughness lower than that of a material of a general resin insulating layer, for example, a photosensitive insulating layer not containing a glass sheet, may be used.

The electronic components 501 and 502 may be connected to the first pads 115 of the circuit board 100 and the second pads 42 of the connection board 10 to thereby be mounted on the printed circuit board.

The electronic components 510 and 502 may include various electronic devices, such as a passive device and an active device, and may generally include any electronic device able to be mounted on or embedded in a printed circuit board.

The electronic components 501 and 502 may be connected to each other by a signal line formed in the microcircuit structure 10A.

Generally, a relatively expensive product, such as a silicon interposer, or the like, is required in order to connect electronic components to each other. However, according to the present embodiment, a general resin board may be used, whereby a mismatch of coefficients of thermal expansion between an interposer board and an electronic component mounted on the interposer board may be significantly decreased, a degree of adhesion between the interposer board and an electronic component mounted on the interposer board may be improved, and a relatively inexpensive interposer may be implemented.

In addition, the core insulating layer of the connection board may be relatively thicker than the insulating layer of the circuit board, whereby the warpage of the printed circuit board may be easily controlled.

Further, the microcircuit structure may be formed on a portion of the connection board to decrease an area to which a novel method is applied, whereby investment costs may be decreased and existing infrastructure may be utilized as much as possible.

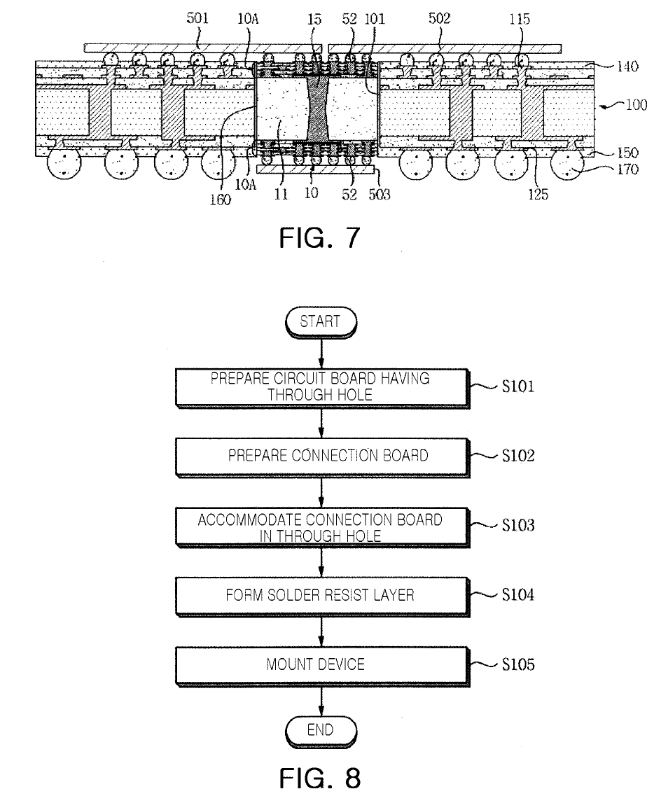

FIG. 7 illustrates a cross-sectional view of an example of an electronic component module according to the present disclosure. Descriptions of components overlapped with those of the printed circuit boards and the electronic component module described above among components of the electronic component module illustrated in FIG. 7 will be omitted.

Referring to FIG. 7, the electronic component module includes electronic components 501, 502, and 503 mounted on a printed circuit board.

The printed circuit board includes a circuit board 100 having a through hole 101 and a connection board 10 accommodated in the through hole 101.

In this example, the circuit board 100 is a multilayer printed circuit board including a plurality of circuit layers and a plurality of insulating layers, and at least one of the insulating layers is interposed between the circuit layers in order to insulate the plurality of circuit layers from each other. For example, the circuit board 100 may be a BGA board including a general core board.

The circuit layers include first pads 115 and 125 for forming connections to external products, such as electronic components, or the like.

The electronic components 501 and 502 are mounted on the first pads 115 through flip-chip bonding, solder balls 170 are mounted as external connection terminals on the first pads 125, and the printed circuit board is connected to an external product such as a main board (not illustrated) through the solder balls 170.

The connection board 10 includes a core insulating layer 11 and microcircuit structures 10A formed on both surfaces of the core insulating layer 11. The microcircuit structures 10A formed on both surfaces of the core insulating layer 11 are electrically connected to each other by a via 15 penetrating through the core insulating layer 11.

The microcircuit structure 10A includes a plurality of circuit layers and a plurality of insulating layers interposed between the plurality of circuit layers in order to insulate the plurality of circuit layers from each other.

The circuit layers of the microcircuit structure 10A have a micropattern having a pitch smaller than that of the circuit layers of the circuit board 100.

The circuit layers of the microcircuit structure 10A include a circuit pattern serving as a signal line connecting a plurality of electronic components mounted on the printed circuit board to each other.

The circuit layers of the microcircuit structure 10A include second pads 52 for forming connections to external products such as electronic components, or the like.

The second pads 52 have a pitch smaller than that of the first pads 115 and 125.

As the insulating layer used in the microcircuit structure 10A, a photosensitive insulating layer may be used so that microcircuits may be easily formed. As the insulating layer used in the microcircuit structure 10A, a photosensitive insulating layer having a level of surface roughness lower than that of a material of a general resin insulating layer, for example, a photosensitive insulating layer not containing a glass sheet, may be used.

The electronic components 501 and 502 are connected to the first pads 115 of the circuit board 100 and the second pads 52 of the connection board 10 to thereby be mounted on an upper surface of the printed circuit board, and the electronic component 503 is connected to the second pads 52 of the connection board 10 to thereby be mounted on a lower surface of the printed circuit board.

The electronic components 510, 502, and 503 may include various electronic devices such as a passive device and an active device, and may generally include any electronic device able to be mounted on or embedded in the printed circuit board.

Generally, a relatively expensive product such as a silicon interposer, or the like, is required in order to connect electronic components to each other. However, according to the present example, a general resin board may be used, whereby a mismatch of coefficients of thermal expansion between an interposer board and an electronic component mounted on the interposer board may be significantly decreased, a degree of adhesion between the interposer board and an electronic component mounted on the interposer board may be improved, and a relatively inexpensive interposer may be implemented.

In addition, the core insulating layer of the connection board may be relatively thicker than the insulating layer of the circuit board, whereby the warpage of the printed circuit board may be easily controlled.

Further, the microcircuit structure may be formed on portions of both surfaces of the connection board to decrease an area to which a novel method is applied, whereby investment costs may be decreased and existing infrastructure may be utilized as much as possible. Further, the electronic components may be mounted on both connection boards, such that an effect similar to 3-D stacking may be obtained.

### Method of Manufacturing Printed Circuit Board/Electronic Component Module

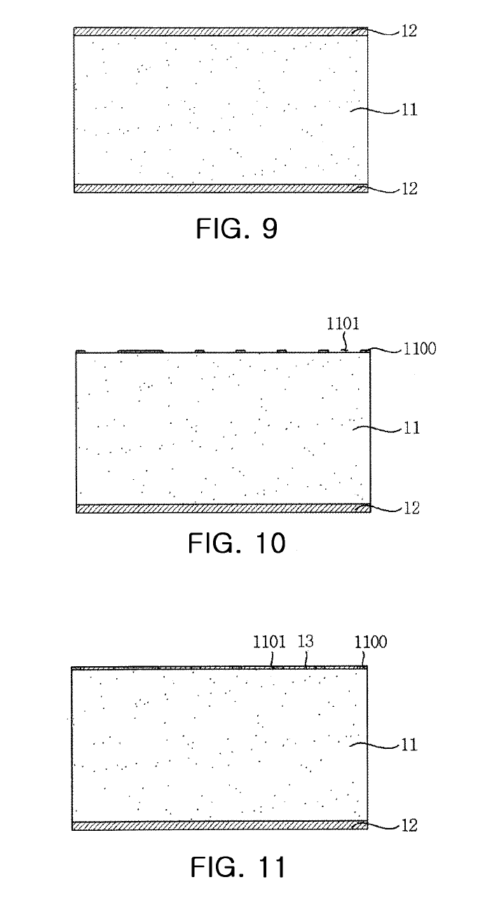

FIG. 8 is a flowchart illustrating an example of a method of manufacturing a printed circuit board and an electronic component module; and FIGS. 9 through 22 are cross-sectional views sequentially illustrating an example of a method of manufacturing a printed circuit board and an electronic component module according to FIG. 8.

Referring to FIG. 8, the method of manufacturing a printed circuit board and an electronic component module involves preparing a circuit board having a through hole (S101), preparing a connection board (S102), accommodating the connection board in the through hole (S103), forming a solder resist layer (S104), and mounting a device (S105).

Hereinafter, respective operations will be described with reference to cross-sectional views illustrated in FIGS. 9 through 22.

An example of a process of manufacturing a connection board will be described with reference to FIGS. 9 through 16.

First, referring to FIG. 9, the core insulating layer 11 having the metal layers 12 formed on both surfaces thereof is prepared.

The core insulating layer 11 may be formed of any insulating resin generally used as an insulating material in the manufacturing of printed circuit boards. For example, the core insulating layer 11 may be formed of a thermosetting resin such as an epoxy resin, a thermoplastic resin such as polyimide, a resin formed by impregnating a reinforcing material such as a glass fiber or an inorganic filler in the thermosetting resin and the thermoplastic resin. The insulating layers may be formed of a resin, such as prepreg, ABF, FR-4, BT, or the like.

The metal layer 12 may be formed of the same material as that of a general circuit layer. For example, the circuit layer may be formed of copper (Cu).

As the core insulating layer 11 having the metal layers 12 formed on both surfaces thereof, for example, a general double-sided copper clad laminate may be used.

Next, referring to FIG. 10, a plating resist layer 1100 patterned to have predetermined openings 1101 is formed on an upper surface of the core insulating layer 11.

The plating resist layer 1100 may be formed of a general liquid-state or film-type dry film.

In this example, although not illustrated, a seed layer may be formed by sequentially performing half-etching and electroless plating on the metal layer 12 formed on the upper surface of the core insulating layer 11 before the plating resist layer 1100 is formed.

Next, referring to FIG. 11, a first circuit layer 13 is formed in the openings 1101 through electroless plating and/or electroplating.

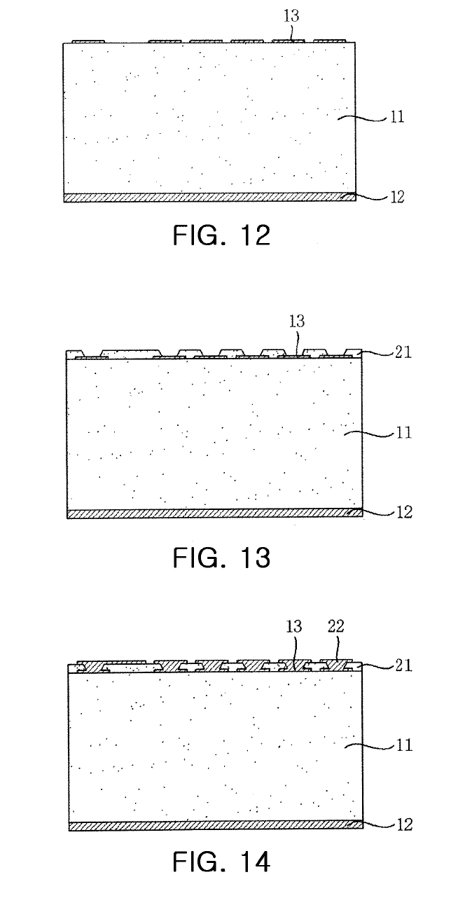

Next, referring to FIG. 12, the plating resist layer 1100 is removed, and referring to FIG. 13, after a first photosensitive insulating layer 21 is formed, via holes are formed in the first photosensitive insulating layer 21 through a photolithography process including general exposure and development.

Next, referring to FIG. 14, a second circuit layer 22 is formed through electroless plating or electroplating.

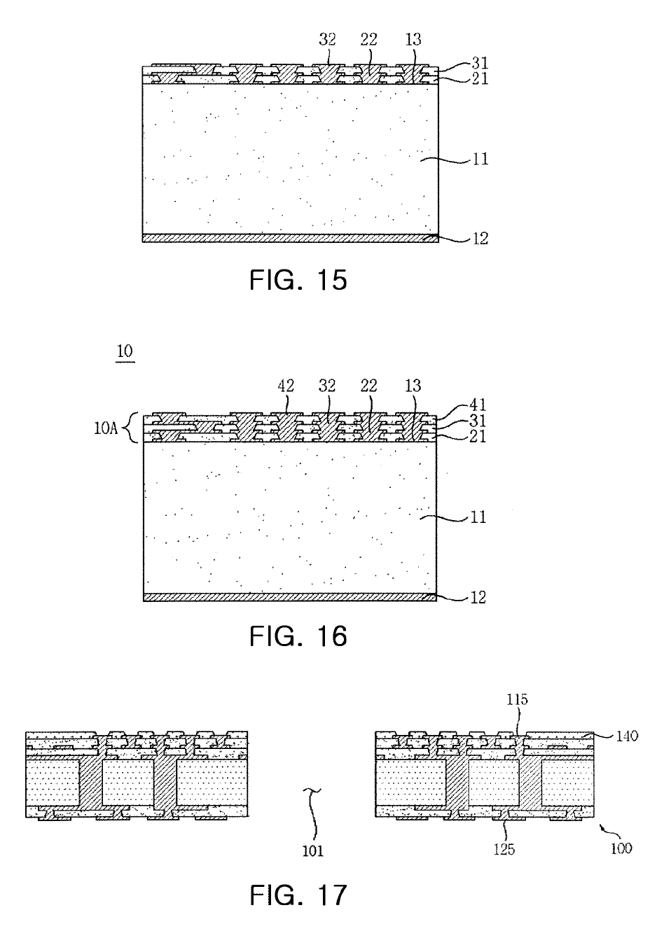

Next, referring to FIG. 15, after a second photosensitive insulating layer 31 is formed, a third circuit layer 32 is formed, and referring to FIG. 16, after a third photosensitive insulating layer 41 is formed, a fourth circuit layer including second pads 42 is formed.

Although four circuit layers have been illustrated as an example of a microcircuit structure in FIGS. 9-16, the number of circuit layers may be modified depending on a type of electronic component in which the method of manufacturing a printed circuit board and an electronic component is actually used. In addition, the circuit layers may be formed by any method of forming circuits known in the art. For example, the circuit layers may be formed by a semi-additive process (SAP), a modified semi-additive process (MSAP), an additive process, a subtractive process, or the like.

Through the processes as described above, the connection board 10 having the microcircuit structure 10A formed on the upper surface of the core insulating layer 11 and the metal layer 12 formed on the lower surface of the core insulating layer 11 is prepared.

In this example, a thickness of the metal layer 12 formed on the lower surface of the core insulating layer 11 may be adjusted depending on a purpose of the desired electronic component, such as a heat dissipation function, or the like.

Next, referring to the example illustrated in FIG. 17, a printed circuit board having a through hole 101 is prepared as the circuit board 100.

In this example, the circuit board 100 is a multilayer printed circuit board including a plurality of circuit layers and a plurality of insulating layers interposed between the plurality of circuit layers in order to insulate the plurality of circuit layers from each other. As the circuit board 100, for example, a BGA board may be used.

The circuit board 100 also includes blind vias and through-vias connecting interlayer circuit layers to each other.

The circuit layers includes the first pads 115 and 125 for forming connections to external products such as electronic components, or the like.

The through hole 101 of the circuit board 100 is a region perforated in order to accommodate the connection board 10 in the circuit board 100, and a size and a shape of the through hole 101 may be determined to allow the connection board 10 to be easily inserted thereinto.

A method of perforating the printed circuit board to form the through hole 101 is not limited, and, for example, mechanical drilling, or the like, may be used.

A first solder resist layer 140 exposing the first pads 115 of the outermost layer may be formed on an upper surface of the circuit board 100.

Meanwhile, although a case in which the first solder resist layer 140 is formed on the circuit board 100 has been described, the first solder resist layer 140 is not limited to being formed on the circuit board 100.

For example, after a carrier film is removed, build-up layers may be simultaneously formed on upper surfaces of the circuit board and the connection board accommodated in the circuit board, the first solder resist layer 140 may be formed on upper surfaces of the build-up layers.

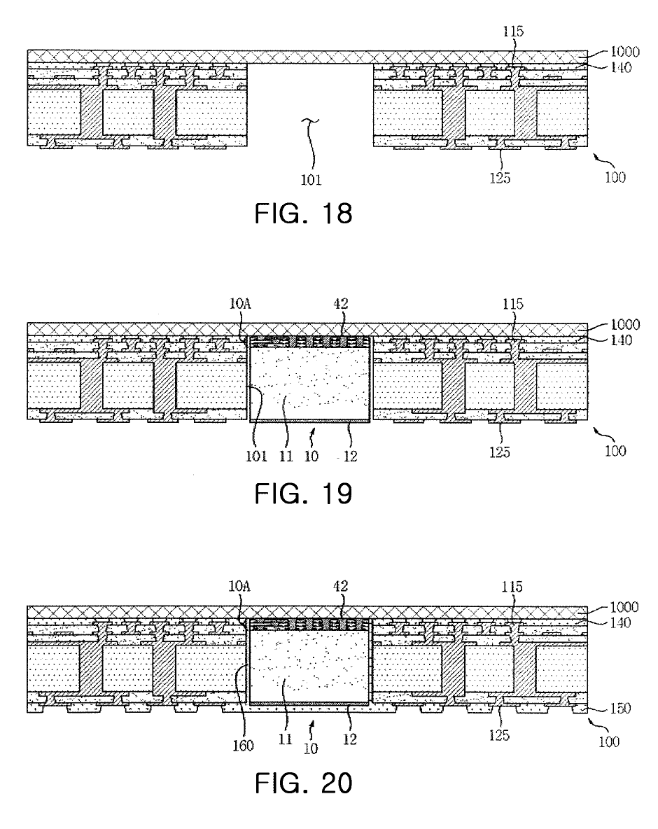

Next, referring to FIG. 18, a carrier film 1000 is attached to the upper surface of the circuit board 100.

The carrier film 1000 may be a member serving as a support on which the circuit board 100 and the connection board 10 to later be inserted into the circuit board may be stably accommodated, and may be formed of any material that may be easily attached and detached while serving as the support.

For example, an adhesive member that loses its adhesion when heat is applied thereto to exhibit a non-adhesive feature may be used as the carrier film 1000. With the use of such an adhesive member, the board may be easily fixed to a location and then may be easily removed by a heat treatment. An example of an adhesive representing a non-adhesive feature at the time of being heat-treated may include a urethane foaming tape, or the like; however, the adhesive member is not limited thereto.

Next, referring to FIG. 19, the connection board 10 is accommodated in the through hole 101 of the circuit board 100.

Next, referring to FIG. 20, a second solder resist layer 150 is formed on lower surfaces of the circuit board 100 and the connection board 10 to which the carrier film 1000 is not attached, and openings exposing a plurality of first pads 125 may be formed in the second solder resist layer 150.

Meanwhile, although not illustrated, build-up layers including circuit build-up layers and/or insulating build-up layers may be additionally formed, if necessary, before the solder resist layer is formed.

Optionally, a surface treatment layer may be formed on the first pads 125 exposed through the openings of the solder resist layer.

In this example, the resin filler 160 is disposed between the through hole 101 of the circuit board 100 and the connection board 10 to secure the connection board 10 within the through hole 101.

The resin filler 160 may be formed through a separate resin filling process or be formed by inserting a solder resist in an empty space in a process of forming the solder resist layer on the outermost layer.

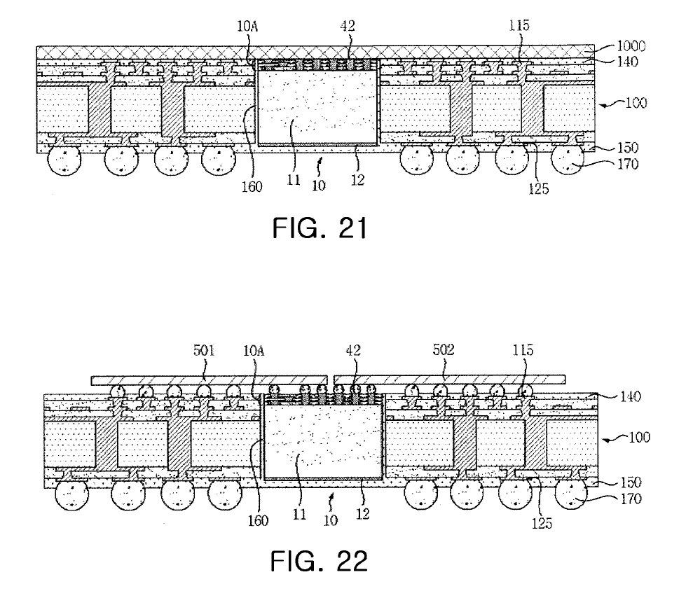

Next, referring to FIG. 21, the solder balls 170 are provided as external connection terminals on the first pads 125 that are exposed.

The printed circuit board may be later connected to another electronic component, upper and lower packages, or an external product such as a motherboard through the solder balls 170 as described above.

Next, referring to FIG. 22, the carrier film 1000 is removed, and the electronic components 501 and 502 are mounted on an upper surface of the printed circuit board.

The electronic components 501 and 502 are mounted on the upper surface of the printed circuit board by connecting to the first and second pads 115 and 42 to establish an electrical connection.

The electronic components 501 and 502 may be connected to each other by a signal line implemented in the microcircuit structure 10A of the connection board 10.

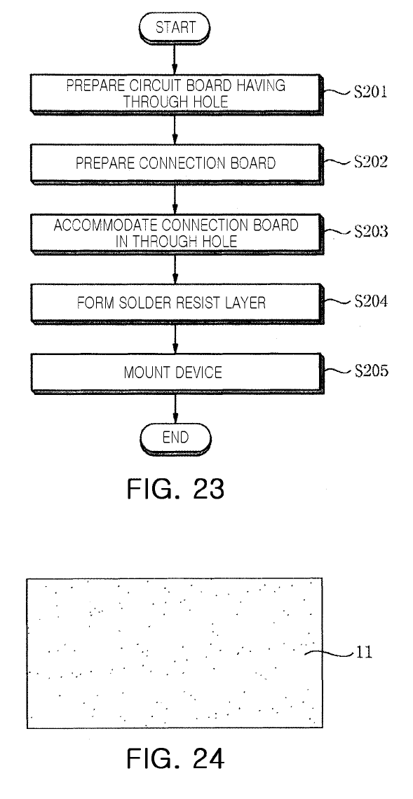

FIG. 23 is a flowchart illustrating another example of a method of manufacturing a printed circuit board and an electronic component module according to the present disclosure; and FIGS. 24 through 38 are cross-sectional views sequentially illustrating the example of the method of manufacturing a printed circuit board and an electronic component module.

Referring to FIG. 23, the example of the method of manufacturing a printed circuit board and an electronic component module includes preparing a circuit board having a through hole (S201), preparing a connection board (S202), accommodating the connection board in the through hole (S203), forming a solder resist layer (S204), and mounting a device (S205).

Hereinafter, respective processes will be described with reference to cross-sectional views illustrated in FIGS. 24 through 38.

A process of manufacturing a connection board according to the example illustrated in FIG. 23 will be described in detail with reference to FIGS. 24 through 32.

First, referring to FIG. 24, the core insulating layer 11 is prepared.

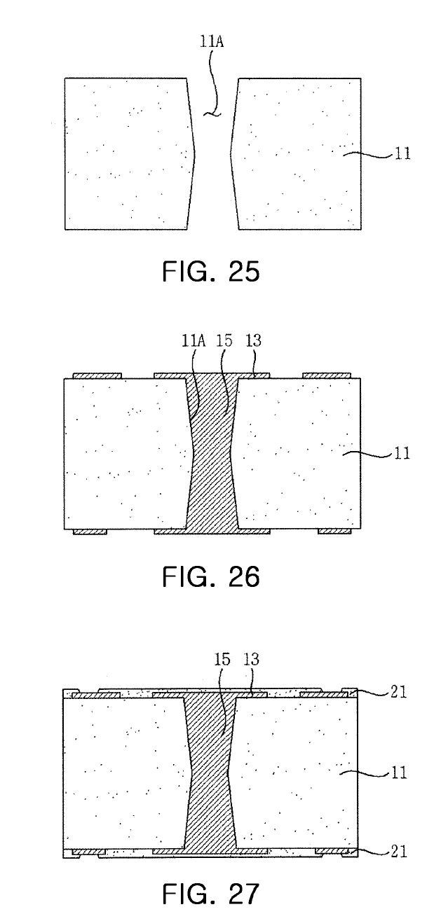

Next, referring to FIG. 25, a through-hole 11A is formed to penetrate through the core insulating layer 11.

The through-hole 11A may be formed by, for example, performing laser drilling on both surfaces of the core insulating layer 11.

Although an example in which the through-hole has a hourglass shape is illustrated in FIG. 25, a shape of the through-hole is not limited thereto.

Next, referring to FIG. 26, first circuit layers 13 are formed on both surfaces of the core insulating layer 11 as well as in the through-hole 11A through electroless and electro metal plating.

The first circuit layers 13 may include a via 15 penetrating through the core insulating layer 11.

Next, referring to FIG. 27, after first photosensitive insulating layers 21 are formed, via holes are formed in the first photosensitive insulating layers 21 through a photolithography process including general exposure and development.

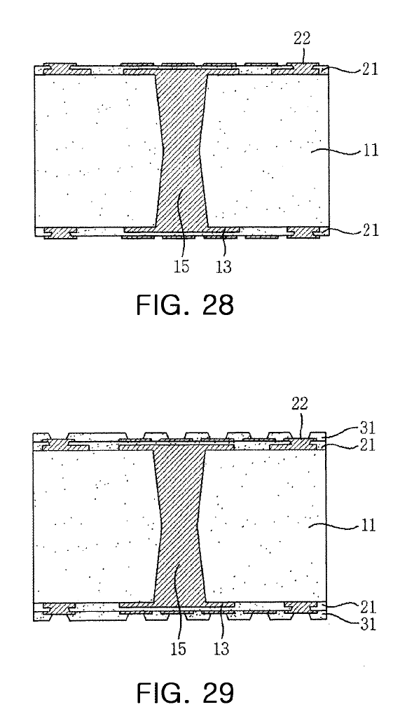

Next, referring to FIG. 28, second circuit layer 22 is formed through electroless and electro metal plating.

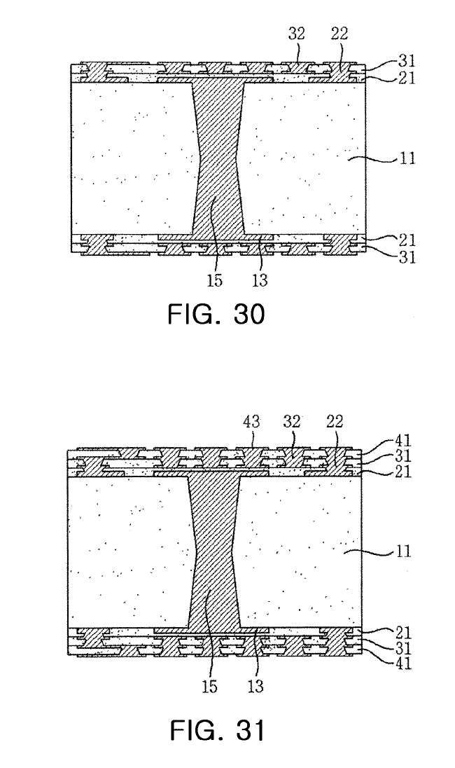

Next, referring to FIGS. 29 and 30, after second photosensitive insulating layers 31 are formed, third circuit layers 32 are formed, and referring to FIG. 31, after third photosensitive insulating layers 41 are formed, fourth circuit layers 43 are formed.

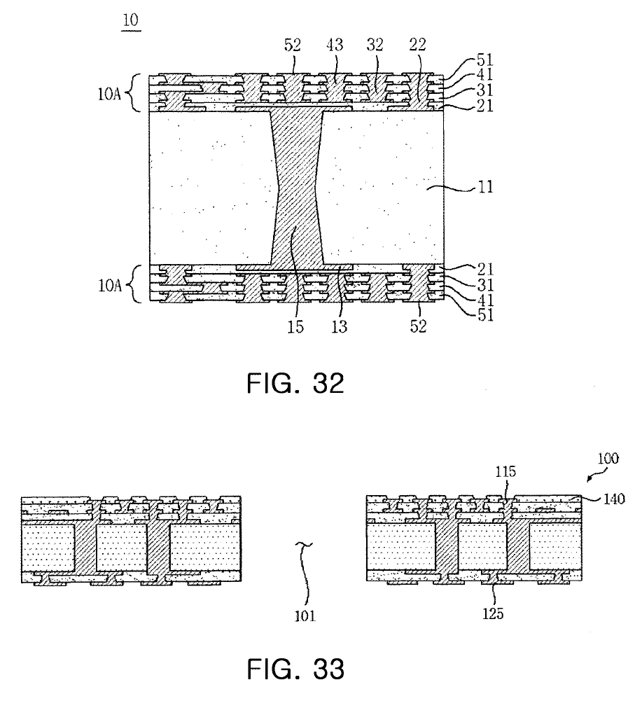

Finally, referring to FIG. 32, after fourth photosensitive insulating layers 51 are formed, fifth circuit layers including second pads 52 are formed.

Through the processes as described above, the connection board 10 having the microcircuit structures 10A formed on both surfaces of the core insulating layer 11 is prepared.

Next, referring to FIG. 33, a printed circuit board having the through hole 101 is prepared as the circuit board 100.

Meanwhile, although an example in which the first solder resist layer 140 is formed on the circuit board 100 has been described, the first solder resist layer 140 is not limited to being formed on the circuit board 100.

For example, after a carrier film is subsequently removed, build-up layers may be simultaneously formed on upper surfaces of the circuit board and the connection board accommodated in the circuit board, the first solder resist layer 140 may be formed on upper surfaces of the build-up layers.

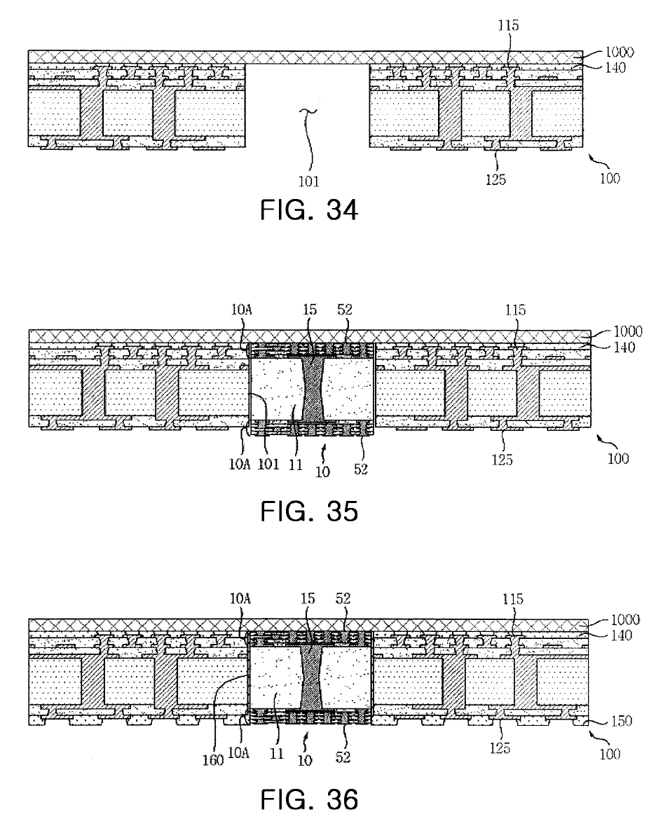

Next, referring to FIG. 34, a carrier film 1000 is attached to the upper surface of the circuit board 100.

Next, referring to FIG. 35, the connection board 10 is accommodated in the through hole 101 of the circuit board 100.

Next, referring to FIG. 36, a second solder resist layer 150 is formed on lower surfaces of the circuit board 100 and the connection board 10 to which the carrier film 1000 is not attached, and openings exposing a plurality of first pads 125 are formed in the second solder resist layer 150.

Next, referring to FIG. 37, the solder balls 170 are provided as external connection terminals on the first pads 125 that are exposed.

The printed circuit board may subsequently be connected to another electronic component, upper and lower packages, or an external product such as a motherboard through the solder balls 170 as described above.

Meanwhile, although an example in which the second solder resist layer 150 is formed and the solder balls 170 are mounted on the first pads 125 before the carrier film 1000 is removed has been described by way of example, the formation of the second solder resist layer 150 and the mounting of the solder balls 170 are not limited thereto.

For example, the formation of the second solder resist layer 150 and the mounting of the solder balls 170 may also be performed after the carrier film 1000 is removed.

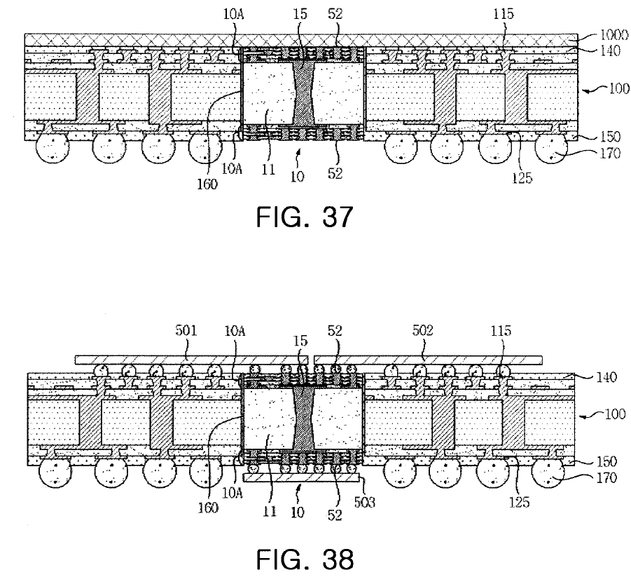

Next, referring to FIG. 38, the carrier film 1000 is removed, and the electronic components 501, 502, and 503 are mounted on both surfaces of the printed circuit board.

The electronic components 501 and 502 are connected to the first and second pads 115 and 52 to thereby be mounted on an upper surface of the printed circuit board.

The electronic components 501 and 502 may be connected to each other by a signal line implemented in the microcircuit structure 10A of the connection board 10.

In addition, the electronic component 503 is connected to the second pads 52 to thereby be mounted on a lower surface of the printed circuit board.

The plurality of electronic components 501, 502, and 503 may also be connected to each other by a circuit pattern implemented in the microcircuit structure 10A.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A printed circuit board comprising:
a circuit board comprising a through hole and a first circuit pattern; and
a connection board having a microcircuit structure comprising a second circuit pattern, the connection board accommodated in the through hole.

2. The printed circuit board of claim 1, wherein the circuit board is a multilayer board comprising a plurality of circuit layers and insulating layers, and
at least one of the insulating layers is interposed between the plurality of circuit layers.

3. The printed circuit board of claim 1, wherein the first circuit pattern comprises first pads for mounting electronic components.

4. The printed circuit board of claim 1, wherein the microcircuit structure is disposed on one surface or both surfaces of the connection board.

5. The printed circuit board of claim 1, wherein the microcircuit structure comprises microcircuit layers disposed on both surfaces of the connection board and electrically connected to each other by a via.

6. The printed circuit board of claim 1, wherein the microcircuit structure comprises a plurality of circuit layers and insulating layers, and
at least one of the insulating layers is interposed between the plurality of circuit layers.

7. The printed circuit board of claim 6, wherein the insulating layer is a photosensitive insulating layer.

8. The printed circuit board of claim 1, wherein the second circuit pattern comprises a signal line for connecting electronic components to each other.

9. The printed circuit board of claim 1, wherein the second circuit pattern comprises second pads for mounting electronic components.

10. The printed circuit board of claim 1, wherein the second circuit pattern comprises a micropattern having a pitch smaller than that of the first circuit pattern.

11. The printed circuit board of claim 1, further comprising a build-up layer including an insulating build-up layer and a circuit build-up layer disposed on the circuit board and the connection board.

12. The printed circuit board of claim 1, further comprising a solder resist layer disposed on the circuit board.

13. The printed circuit board of claim 1, further comprising a resin filler disposed between the connection board and the through hole.

14. The printed circuit board of claim 13, wherein the resin filler is a solder resist.

15. An electronic component module comprising:
a printed circuit board comprising a circuit board having a through hole and a first circuit pattern, and a connection board having a microcircuit structure comprising a second circuit pattern, the connection board accommodated in the through hole; and
electronic components mounted on one surface or both surfaces of the printed circuit board.

16. The electronic component module of claim 15, wherein the second circuit pattern comprises a micropattern having a pitch smaller than that of the first circuit pattern.

17. A method of manufacturing a printed circuit board, the method comprising:
preparing a circuit board having a through hole and comprising a first circuit pattern; and
inserting a connection board in the through hole,
wherein the connection board comprises a microcircuit structure comprising a second circuit pattern.

18. The method of claim 17, further comprising preparing the connection board prior to the inserting of the connection board in the through hole such that the circuit board is a multilayer board comprising circuit layers and insulating layers disposed on a first side of a core insulating layer and on a second side of the core insulating layer opposite the first side, a via electrically connecting the first side to the second side of the connection board.

19. The method of claim 18, further comprising mounting one or more electronic components on one surface or both surfaces of the printed circuit board.
